(19) United States
(12) Patent Application Publication
(10) Pub. No.: US 2023/0413553 A1
(43) Pub. Date: Dec. 21, 2023

(54) SEMICONDUCTOR MEMORY DEVICE AND MANUFACTURING METHOD OF SEMICONDUCTOR MEMORY DEVICE

(71) Applicant: SK hynix Inc., Icheon-si Gyeonggi-do (KR)

(72) Inventor: Kang Sik CHOI, Icheon-si Gyeonggi-do (KR)

(73) Assignee: SK hynix Inc., Icheon-si Gyeonggi-do (KR)

(21) Appl. No.: 17/991,062

(22) Filed: Nov. 21, 2022

(30) Foreign Application Priority Data
May 23, 2022 (KR) 10-2022-0062816

(51) Int. Cl. H01L 27/11582

(52) U.S. Cl. CPC H01L 27/11582

(57) ABSTRACT

There are provided a semiconductor memory device and a manufacturing method thereof. The semiconductor memory device may include a gate stack structure having a stepped structure, which includes a plurality of interlayer insulating layers and a plurality of conductive layers, a tubular insulating layer penetrating the stepped structure of the gate stack structure, and a conductive gate contact connected to an end portion of one of the plurality of conductive layers, the conductive gate contact extending to a central region of the tubular insulating layer.

### CROSS-REFERENCE TO RELATED APPLICATION

The present application claims priority under 35 U.S.C. § 119(a) to Korean patent application number 10-2022-0062816, filed on May 23, 2022, in the Korean Intellectual Property Office, the entire disclosure of which is incorporated herein by reference.

### BACKGROUND

### 1. Technical Field

The present disclosure generally relates to a semiconductor memory device and a manufacturing method of a semiconductor memory device, and more particularly, to a three-dimensional semiconductor memory device and a manufacturing method of a three-dimensional semiconductor memory device.

### 2. Related Art

A semiconductor memory device includes a memory cell array and a peripheral circuit structure connected to the memory cell array. The memory cell array includes a plurality of memory cells capable of storing data. The peripheral circuit structure may supply various operating voltages to the memory cells, and control various operations of the memory cells.

In a three-dimensional semiconductor memory device, a plurality of memory cells may be connected to a plurality of conductive layers stacked to be spaced apart from each other. Each of the plurality of conductive layers may be connected to a peripheral circuit structure via a conductive gate contact corresponding thereto.

Various techniques for simplifying a structure and a manufacturing process of a three-dimensional semiconductor memory device have been developed, but operational reliability may deteriorate due to the development of various techniques.

### SUMMARY

In accordance with an embodiment of the present disclosure, there may be provided a semiconductor memory device including: a gate stack structure including a plurality of interlayer insulating layers and a plurality of conductive layers, which are alternately stacked in a first direction, the gate stack structure having a stepped structure defined by an end portion of each of the plurality of conductive layers extending to a different length; a gap fill insulating layer disposed on the gate stack structure to cover the stepped structure; a tubular insulating layer intersecting the end portion of each of the plurality of conductive layers, the tubular insulating layer extending in the first direction to penetrate the stepped structure of the gate stack structure and the gap fill insulating layer; and a conductive gate contact disposed in a central region of the tubular insulating layer, wherein the conductive gate contact includes a protrusion part penetrating a side portion of the tubular insulating layer to be connected to one conductive layer among the plurality of conductive layers.

In accordance with an embodiment of the present disclosure, there may be provided a semiconductor memory device including: a first conductive layer; a second conductive layer disposed to be spaced apart from the first conductive layer in a first direction; an interlayer insulating layer between the first conductive layer and the second conductive layer; a first tubular insulating pattern penetrating the first conductive layer, the interlayer insulating layer, and the second conductive layer, the first tubular insulating pattern extending in the first direction; a second tubular insulating pattern spaced apart from the first tubular insulating pattern in the first direction, the second tubular insulating pattern extending in the first direction; and a conductive gate contact including a pillar part extending from a central region of the first tubular insulating pattern to a central region of the second tubular insulating pattern and a protrusion part extending between the first tubular insulating pattern and the second tubular insulating pattern from the pillar part, wherein the protrusion part is in contact with a top surface of the second conductive layer.

In accordance with an embodiment of the present disclosure, there may be provided a semiconductor memory device including: a first conductive layer; a second conductive layer disposed to be spaced apart from the first conductive layer in a first direction; an interlayer insulating layer between the first conductive layer and the second conductive layer; a first tubular insulating pattern penetrating the first conductive layer, the interlayer insulating layer, and the second conductive layer, the first tubular insulating pattern extending in the first direction; and a second tubular insulating pattern spaced apart from the first tubular insulating pattern in the first direction, the second tubular insulating pattern extending in the first direction, wherein the second conductive layer extends along an inner wall of the first tubular insulating pattern and an inner wall of the second tubular insulating pattern while passing between the first tubular insulating pattern and the second tubular insulating pattern.

In accordance with an embodiment of the present disclosure, there may be provided a method of manufacturing a semiconductor memory device, the method including: forming a stepped stack structure including a lower first material layer, an upper first material layer disposed to be spaced apart from the lower first material layer in a first direction, and a second material layer between the lower first material layer and the upper first material layer, wherein an end portion of the second material layer extends farther than the upper first material layer in a second direction perpendicular to the first direction; forming a sacrificial pad on the end portion of the second material layer; forming a hole penetrating the lower first material layer, the second material layer, and the sacrificial pad; removing a portion of each of the lower first material layer and the second material layer through the hole such that a first recess region is formed under the sacrificial pad; forming a first tubular insulating pattern in the first recess region; removing the sacrificial pad such that a trench is formed; and forming a conductive gate contact in the trench and a central region of the first tubular insulating pattern.

### BRIEF DESCRIPTION OF THE DRAWINGS

Various examples of embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or additional intervening elements may also be present. Like reference numerals refer to like elements throughout the drawings.

FIG. 1 is a block diagram illustrating a semiconductor memory device in accordance with an embodiment of the present disclosure.

FIGS. 2A and 2B are views schematically illustrating arrangements of a peripheral circuit structure, a memory cell array, a plurality of bit lines, and a doped semiconductor structure in accordance with embodiments of the present disclosure.

FIG. 3 is a circuit diagram illustrating a memory cell array and a block select circuit structure in accordance with an embodiment of the present disclosure.

FIG. 4 is a perspective view illustrating a portion of a semiconductor memory device in accordance with an embodiment of the present disclosure.

FIGS. 5A and 5B are sectional views illustrating a semiconductor memory device in accordance with an embodiment of the present disclosure.

FIGS. 6 and 7 are sectional views illustrating semiconductor memory devices in accordance with embodiments of the present disclosure.

FIGS. 8A, 8B, 8C, 9A, 9B, 10A, 10B, 10C, 11, 12A, 12B, and 13 are process sectional views illustrating a manufacturing method of a semiconductor memory device in accordance with an embodiment of the present disclosure.

FIGS. 14A and 14B are process sectional views illustrating a manufacturing method of a semiconductor memory device in accordance with an embodiment of the present disclosure.

FIGS. 15A, 15B, 16A, 16B, and 16C are process views illustrating a manufacturing method of a semiconductor memory device in accordance with an embodiment of the present disclosure.

FIG. 17 is a block diagram illustrating a configuration of a memory system in accordance with an embodiment of the present disclosure.

FIG. 18 is a block diagram illustrating a configuration of a computing system in accordance with an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Embodiments provide a semiconductor memory device and a manufacturing method of a semiconductor memory device, which may improve operational reliability.

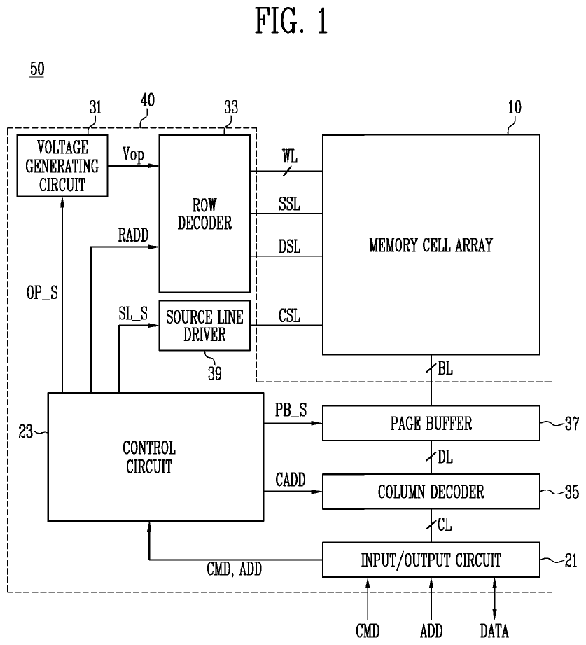

FIG. 1 is a block diagram illustrating a semiconductor memory device in accordance with an embodiment of the present disclosure.

Referring to FIG. 1, the semiconductor memory device 50 may include a peripheral circuit structure 40 and a memory cell array 10.

The peripheral circuit structure 40 may be configured to perform a program operation for storing data in the memory cell array 10, a read operation for outputting data stored in the memory cell array 10, and an erase operation for erasing data stored in the memory cell array 10. In an embodiment, the peripheral circuit structure 40 may include an input/output circuit 21, a control circuit 23, a voltage generating circuit 31, a row decoder 33, a column decoder 35, a page buffer 37, and a source line driver 39.

The memory cell array 10 may include a plurality of cells for a NAND flash memory device. Hereinafter, the embodiment of the present disclosure will be described based on the memory cell array 10 of the NAND flash memory device, but the present disclosure is not limited thereto. In an embodiment, the memory cell array 10 may include a plurality of memory cells for a variable resistance memory device or a plurality of memory cells for a ferroelectric memory device.

The plurality of memory cells of the NAND flash memory device may form a plurality of memory cell strings. Each memory cell string may be connected to a drain select line DSL, a plurality of word lines WL, a source select line SSL, a plurality of bit lines BL, and a common source line CSL.

The input/output circuit 21 may transfer, to the control circuit 23, a command CMD and an address ADD, which received from an external device (e.g., a memory controller) of the semiconductor memory device 50. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transfer the operating voltages Vop to the drain select line DSL, the word line WL, and the source select line SSL in response to the row address RADD.

The column decoder 35 may transmit data DATA input from the input/output circuit 21 to the page buffer 37 or transmit data DATA stored in the page buffer 37 to the input/output circuit 21 in response to the column address CADD. The column decoder 35 may exchange data DATA with the input/output circuit 21 through a column line CL. The column decoder 35 may exchange data DATA with the page buffer through a data line DL.

The page buffer 37 may temporarily store data DATA received through the bit line BL in response to the page buffer control signal PB_S. The page buffer 37 may sense a voltage or current of the bit line BL in a read operation.

The source line driver 39 may control a voltage applied to the common source line CSL in response to the source line control signal SL_S.

In order to improve the degree of integration of the semiconductor memory device, the memory cell array 10 may overlap with the peripheral circuit structure 40.

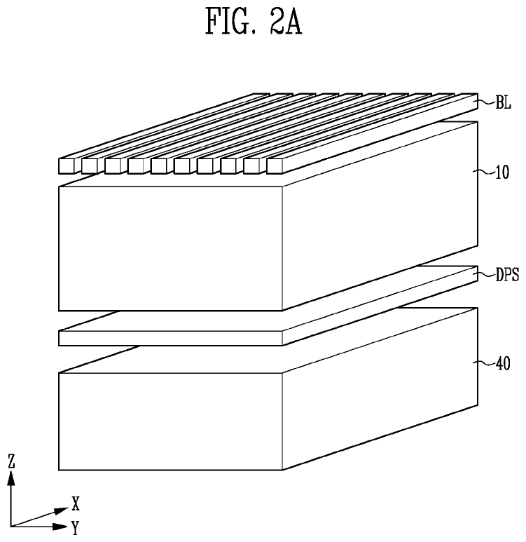

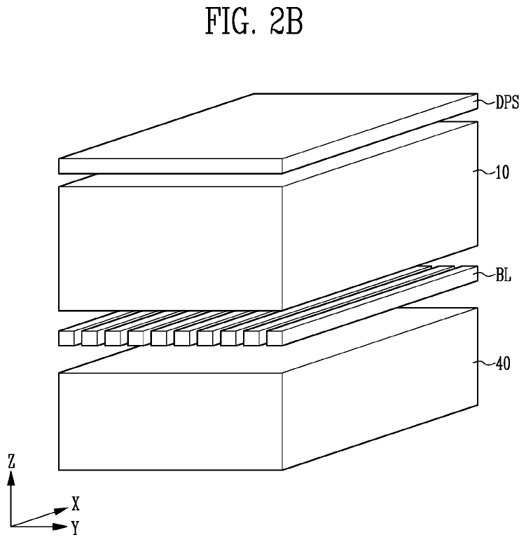

FIGS. 2A and 2B are views schematically illustrating arrangements of a peripheral circuit structure, a memory cell array, a plurality of bit lines, and a doped semiconductor structure in accordance with embodiments of the present disclosure.

Referring to FIGS. 2A and 2B, the semiconductor memory device may include a doped semiconductor structure DSP, a memory cell array 10, and a plurality of bit lines BL.

The doped semiconductor structure DSP may extend on an XY plane. The doped semiconductor structure DSP may be connected to the common source line CSL shown in FIG. 1. The doped semiconductor structure DPS may include at least one of an n-type impurity and a p-type impurity.

The memory cell array 10 may be connected to the common source line CSL shown in FIG. 1 via the doped semiconductor structure DPS. The memory cell array 10 may be disposed between the plurality of bit lines BL and the doped semiconductor structure DPS.

Referring to FIG. 2A, a peripheral circuit structure 40 of the semiconductor memory device may be adjacent to the doped semiconductor structure DPS. Accordingly, the peripheral circuit structure 40, the doped semiconductor structure DPS, the memory cell array, and the plurality of bit lines BL may be arranged in a Z-axis direction. Although not shown in the drawing, a plurality of interconnections may be disposed between the peripheral circuit structure and the doped semiconductor structure DPS, or a plurality of interconnections and a plurality of conductive bonding pads may be disposed between the peripheral circuit structure 40 and the doped semiconductor structure DPS.

Referring to FIG. 2B, the peripheral circuit structure 40 of the semiconductor memory device may be adjacent to the plurality of bit lines BL. Accordingly, the peripheral circuit structure 40, the plurality of bit lines BL, the memory cell array 10, and the doped semiconductor structure DSP may be arranged in the Z-axis direction. Although not shown in the drawing, a plurality of interconnections may be disposed between the peripheral circuit structure 40 and the plurality of bit lines BL, or a plurality of interconnections and a plurality of conductive bonding pads may be disposed between the peripheral circuit structure 40 and the plurality of bit lines BL.

A process for manufacturing the semiconductor memory device shown in FIGS. 2A and 2B may be performed in various manners. In an embodiment, a process for forming the memory cell array 10 shown in FIG. 2A or 2B may be performed on the peripheral circuit structure 40. In another embodiment, a first structure including the memory cell array shown in FIG. 2A or 2B may be formed separately from a second structure including the peripheral circuit structure 40. The first structure and the second structure may be bonded to each other through a plurality of conductive bonding pads.

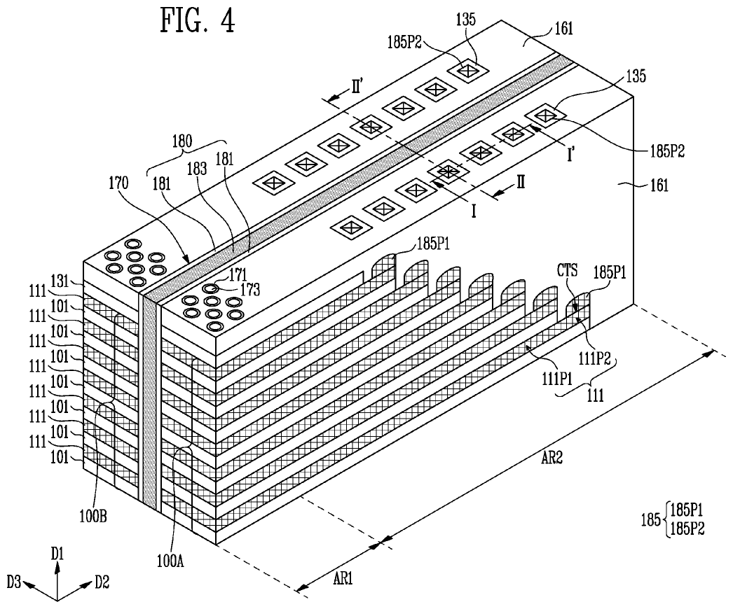

The memory cell array 10 shown in FIG. 2A or 2B may be connected to one bit line corresponding thereto among the plurality of bit lines BL through a channel structure (e.g., 173 shown in FIG. 4). The memory cell array 10 may be connected to the doped semiconductor structure DPS through the channel structure.

The memory cell array 10 shown in FIG. 2A or 2B may include a memory cell string. The memory cell string may be connected to a plurality of conductive layers (e.g., 111 shown in FIG. 4) spaced apart from each other in the Z-axis direction. The plurality of conductive layers may be used as at least one lower select line, at least one upper select line, and a plurality of word lines.

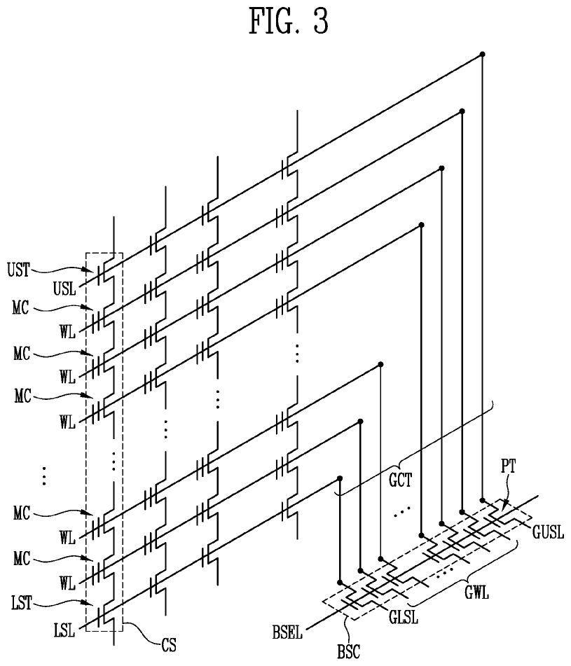

FIG. 3 is a circuit diagram illustrating a memory cell array and a block select circuit structure in accordance with an embodiment of the present disclosure.

Referring to FIG. 3, the memory cell array may include a plurality of memory cell strings CS. Each memory cell string CS may include at least one lower select transistor LST, a plurality of memory cells MC, and at least one upper select transistor UST.

The plurality of memory cells MC may be connected in series between the lower select transistor LST and the upper select transistor UST. One of the lower select transistor LST and the upper select transistor UST may be used as a source select transistor, and the other of the lower select transistor LST and the upper select transistor UST may be used as a drain select transistor. The plurality of memory cells MC may be connected to the doped semiconductor structure DPS shown in FIGS. 2A and 2B via the source select transistor. The plurality of memory cells MC may be connected to the bit line shown in FIGS. 2A and 2B via the drain select transistor.

The plurality of memory cells MC may be respectively connected to a plurality of word lines. An operation of each memory cell MC may be controlled by a gate signal applied to a word line WL corresponding thereto. The lower select transistor LST may be connected to a lower select line LSL. An operation of the lower select transistor LST may be controlled by a gate signal applied to the lower select line LSL. The upper select transistor UST may be connected to an upper select line USL. An operation of the upper select transistor UST may be controlled by a gate signal applied to the upper select line USL.

The lower select line LSL, the upper select line USL, and the plurality of word lines WL may be connected to a block select circuit structure BSC. The block select circuit structure BSC may be included in the row decoder 33 described with reference to FIG. 1. In an embodiment, the block select circuit structure BSC may include a plurality of pass transistors PT respectively connected to the lower select line LSL, the upper select line USL, and the plurality of word lines WL. A plurality of gate electrodes of the plurality of pass transistors PT may be connected to a block select line BSEL. The plurality of pass transistors PT may be configured to transfer signals applied to a plurality of global lines GLSL, GUSL, and GWL to the lower select line LSL, the upper select line USL, and the plurality of word lines WL in response to a block select signal applied to the block select line BSEL.

The block select circuit structure BSC may be connected to the lower select line LSL, the upper select line USL, and the plurality of word lines WL via a plurality of conductive gate contacts GCT.

FIG. 4 is a perspective view illustrating a portion of a semiconductor memory device in accordance with an embodiment of the present disclosure.

Referring to FIG. 4, the semiconductor memory device may include a plurality of gate stack structures 100A and 100B. Each of the plurality of gate stack structures 100A and 100B may include a cell array region AR1 and a contact region AR2. The contact region AR2 may extend from the cell array region AR1. Each of the plurality of stack structures 100A and 100B may be formed in a stepped structure in the contact region AR2.

Each of the plurality of stack structures 100A and 100B may include a plurality of Interlayer insulating layers 101 and a plurality of conductive layers 111, which are alternately stacked in a first direction D1. Each of the plurality of interlayer insulating layers 101 and the plurality of conductive layers 111 may be formed in a flat plate shape parallel to a plane orthogonal to an axis facing in the first direction D1. In an embodiment, each of the plurality of interlayer insulating layers 101 and the plurality of conductive layers 111 may extend in a second direction D2 and a third direction D3. The second direction D2 may be defined as a direction toward the contact region AR2 from the cell array region AR1, and the third direction D3 may be defined as an extending direction of the plurality of bit lines BL shown in FIGS. 2A and 2B. For example, the first direction D1, the second direction D2 and the third direction D3 may be perpendicular to each other.

One of an uppermost conductive layer and a lowermost conductive layer of the plurality of conductive layers 111 may be used as the lower select line LSL shown in FIG. 3, and the other of the uppermost conductive layer and the lowermost conductive layer may be used as the upper select line USL shown in FIG. 3. A plurality of intermediate conductive layers between the lower select line LSL and the upper select line USL among the plurality of conductive layers 111 may be used as the plurality of word lines WL shown in FIG. 3. The uppermost conductive layer among the plurality of conductive layers 111 may be covered by an upper insulating layer 131.

Each conductive layer 111 may include an interposition part 111P1 and an end portion 111P2 extending in the second direction D2 from the interposition part 111P. The stepped structure of each of the plurality of gate stack structures 100A and 100B may be defined by an end portion 111P2 of each of the plurality of conductive layers 111 extending to a different length. The interposition portion 111P1 of each of the plurality of conductive layers 111 may be disposed between a plurality of interlayer insulating layers 101 adjacent to each other in the first direction D1, or be disposed between an interlayer insulating layer 101 and the upper insulating layer 131, which are adjacent to each other in the first direction D1. The interposition part 111P1 of the conductive layer 111 may extend toward the cell array area AR1 from the end portion 111P2 of the conductive layer 111.

The semiconductor memory device may include a gap fill insulating layer 161 covering each of the gate stack structures 100A and 100B. The gap fill insulating layer 161 may cover the stepped structure of each of the plurality of gate stack structures 100A and 100B. The gap fill insulating layer 161 may extend to cover the upper insulating layer 131.

The semiconductor memory device may include a channel structure 173 and a memory layer 171. The channel structure 173 and the memory layer 171 may penetrate the plurality of interlayer insulating layers 101 and the plurality of conductive layers 111 in the cell array region AR1. The memory layer 171 may be interposed between the channel structure 173 and a gate stack structure 100A or 100B corresponding thereto. The memory layer 171 may be surrounded by the interposition part 111P1 of each of the plurality of conductive layers 111. The memory layer 171 may include a tunnel insulating layer surrounding an outer wall of the channel structure 173, a data storage layer surrounding an outer wall of the tunnel insulating layer, and a first blocking insulating layer surrounding an outer wall of the data storage layer. The tunnel insulating layer, the data storage layer, and the first blocking insulating layer may extend in the first direction D1. The data storage layer may include a charge trap layer, a floating gate layer, a variable resistance layer, or a ferroelectric layer. In an embodiment, the data storage layer may be formed as a nitride layer capable of trapping charges. The first blocking insulating layer may include oxide capable of blocking charges, and a tunnel insulating layer may include silicon oxide through which charges can tunnel.

Although not shown in the drawing, the semiconductor memory device may further include a second blocking insulating layer. The second blocking insulating layer may extend along an interface between each conductive layer 111 and an interlayer insulating layer 101 adjacent thereto and an interface between each conductive layer 111 and the memory layer 171. The second blocking insulating layer may be formed of an insulating material having a dielectric constant higher than a dielectric constant of the first blocking insulating layer. In an embodiment, the second blocking insulating layer may include a metal oxide layer such as an aluminum oxide layer. Any one of the first blocking insulating layer and the second blocking insulating layer may be omitted.

The plurality of gate stack structures 100A and 100B may be spaced apart from each other by a slit 170. The slit 170 may extend in the second direction D2 to penetrate the gap fill insulating layer 161.

A vertical structure 180 may be disposed inside the slit 170. In an embodiment, the vertical structure 180 may include a conductive source contact 183 disposed in the slit 170 and a sidewall insulating layer 181 between each of the plurality of stack structures 100A and 100B and the conductive source contact 183. The conductive source contact 183 may be connected to the doped semiconductor structure DPS shown in FIGS. 2A and 2B. Although not shown in the drawing, in another embodiment, the vertical structure 180 may be formed of an insulating material filling the slit 170.

The semiconductor memory device may include a plurality of tubular insulating layers 135 and a plurality of conductive gate contacts 185 respectively corresponding thereto. The plurality of tubular insulating layers 135 may extend in the first direction D1 to penetrate the stepped structure of each of the plurality of gate stack structures 100A and 100B and the gap fill insulating layer 161. Each tubular insulating layer 135 may intersect an end portion 111P2 of a conductive layer 111 corresponding thereto to penetrate the end portion 111P2. Tubular structures are not necessarily round in cross section. For example, the tubular insulating layers 135 are shown in FIG. 4 with square cross sections and may have rectangular or other cross sections in other embodiments.

Each of the plurality of conductive gate contacts 185 may include a protrusion part 185P1 and a pillar part 185P2. The pillar part 185P2 may be disposed in a central region of a tubular insulating layer 135 corresponding thereto. The protrusion part 185P1 may protrude laterally from the pillar part 185P2. The protrusion part 185P1 may penetrate a side portion of the tubular insulating layer 135 to form a contact surface CTS with an end portion 111P2 of a conductive layer 111 corresponding thereto.

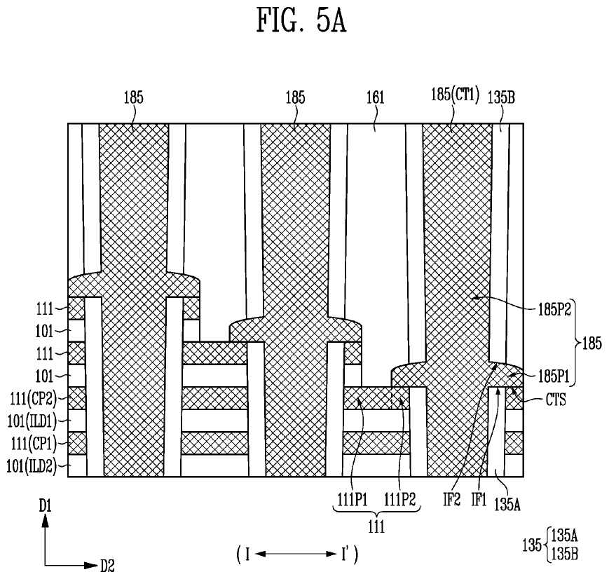

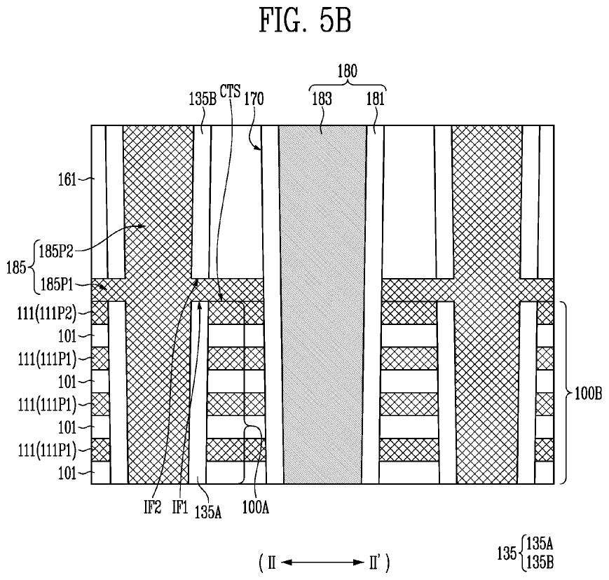

FIGS. 5A and 5B are sectional views illustrating a semiconductor memory device in accordance with an embodiment of the present disclosure. FIG. 5A is a sectional view of the semiconductor memory device taken along line I-I′ shown in FIG. 4, and FIG. 5B is a sectional view of the semiconductor memory device taken along line II-II′ shown in FIG. 4.

Referring to FIGS. 5A and 5B, the plurality of conductive gate contacts 185 and the plurality of conductive layers 111 may correspond one-to-one to each other, and each of the plurality of conductive gate contacts 185 may be in contact with a conductive layer 111 corresponding thereto.

Each tubular insulating layer 135 may be isolated into a first tubular insulating pattern 135A and a second tubular insulating pattern 135B by a protrusion part 185P1 of a conductive gate contact 185 corresponding thereto. The first tubular insulating pattern 135A may extend in the first direction D1 to penetrate a stepped structure of a gate stack structure 100A or 100B corresponding thereto. The second tubular insulating pattern 135B may be spaced apart from the first tubular insulating pattern 135A in the first direction D1 by the protrusion part 185P1. The second tubular insulating pattern 135B may extend in the first direction D1 to penetrate the gap fill insulating layer 161.

The pillar part 185P2 of the conductive gate contact 185 may extend from a central region of the first tubular insulating pattern 135A to a central region of the second tubular insulating pattern 135B. The protrusion part 185P1 of the conductive gate contact 185 may extend onto an end portion 111P2 of a conductive layer 111 corresponding to the protrusion part 185P1 while passing between the first tubular insulating pattern 135A and the second tubular insulating pattern 135B.

The first tubular insulating pattern 135A may form a first interface IF1 with the protrusion part 185P1, and the second tubular insulating pattern 135B may form a second interface IF2 with the protrusion part 185P1. The first interface IF1 and the second interface IF2 may overlap with each other in the first direction D1.

The end portion 111P2 of the conductive layer 111 may include a top surface facing in the first direction D1. The top surface of the end portion 111P2 may form a contact surface CTS with a protrusion part 185P1 corresponding thereto. The contact surface CTS may extend in the second direction D2 and the third direction D3 along an end portion 111P2 of a conductive layer 111 corresponding thereto.

Referring to FIG. 5A, the plurality of conductive layers 111 may include at least one lower conductive layer disposed under the contact surface CTS with respect to the contact surface CTS. The plurality of interlayer insulating layers 101 may include at least one lower interlayer insulating layer disposed under the contact surface CTS with respect to the contact surface CTS. The first tubular insulating pattern 135A may continuously extend to penetrate the lower interlayer insulating layer and the lower conductive layer from a protrusion part 185P1 of a conductive gate contact 185 corresponding thereto. For example, the plurality of conductive gate contacts 185 may include a first conductive gate contact CT1. The plurality of conductive layers 111 may include a first conductive layer CP1 and a second conductive layer CP2 spaced apart from the first conductive layer CP1 in the first direction D1. The second conductive layer CP2 may be defined as a contact conductive layer in contact with a protrusion part 185P1 of the first conductive gate contact CT1, and the first conductive layer CP1 may be defined as a lower conductive layer. The plurality of interlayer insulating layers 101 may include a first interlayer insulating layer ILD1 between the first conductive layer CP1 and the second conductive layer CP2 and a second interlayer insulating layer ILD2 spaced apart from the first interlayer insulating layer ILD1 with the first conductive layer CP1 interposed therebetween. Each of the first interlayer insulating layer ILD1 and the second interlayer insulating layer ILD2 may be defined as a lower insulating layer.

According to the above-described definition, a first tubular insulating pattern 135 corresponding to the first conductive gate contact CT1 may continuously extend to penetrate the first conductive layer CP1, the first interlayer insulating layer ILD1, and the second interlayer insulating layer ILD2 from the protrusion part 185P1 of the first conductive gate contact Cr1. In FIG. 5A, it is illustrated that a portion of the first conductive layer CP1 is omitted. However, the first conductive layer CP1 may protrude more laterally than the second conductive layer CP2 for the purpose of the stepped structure as shown in FIG. 4. In an embodiment, the first conductive layer CP1 may extends farther than the second conductive layer CP2 in the second direction D2.

In accordance with the above-described embodiment, the first tubular insulating pattern 135A is not cut by a lower interlayer insulating layer (e.g., ILD1 or ILD2), but may be continuous along a sidewall of the lower interlayer insulating layer. Although not shown in the drawing, in a comparative example, a first tubular insulating pattern may be disposed between the lower interlayer insulating layers (e.g., ILD1 and ILD2) in only a layer in which a lower conductive layer (e.g., CP1) is disposed. As compared with the first tubular insulating pattern in accordance with the comparative example, the first tubular insulating pattern 135A in accordance with the above-described embodiment is formed, so that occurrence of voids and seams may be reduced.

Referring to FIG. 5B, a protrusion part 185P1 of each conductive gate contact 185 may extend toward the slit 170 along an end portion 111P2 of a conductive layer 111 corresponding thereto. The conductive source contact 183 may be spaced apart from the plurality of interlayer insulating layers 101, the plurality of conductive layers 111, and the protrusion part 185P1 of the conductive gate contact 185 by the sidewall insulating layer 181.

Referring to FIGS. 5A and 5B, the protrusion part 185P1 and the pillar part 185P2 of the conductive gate contact 185 may be formed with an integrated conductive material.

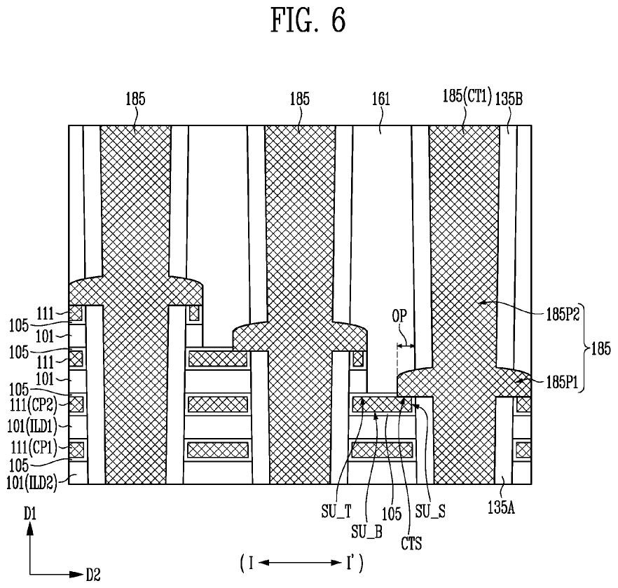

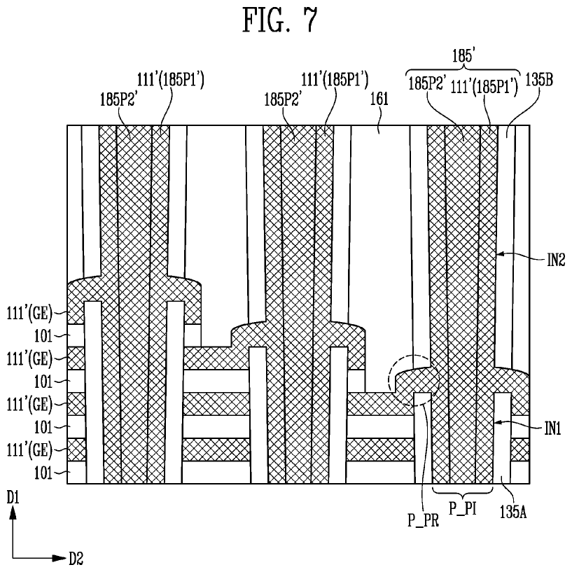

FIGS. 6 and 7 are sectional views illustrating semiconductor memory devices in accordance with embodiments of the present disclosure. Each of FIGS. 6 and 7 illustrates a section of a semiconductor memory device taken along the line I-I′ shown in FIG. 4. Hereinafter, overlapping descriptions of the same components as those shown in FIGS. 5A and 5B will be omitted.

Referring to FIGS. 6 and 7, as described with reference to FIGS. 5A and 5B, a plurality of Interlayer insulating layers 101 and a plurality of conductive layers 111 or 111′ may be penetrated by a first tubular insulating pattern 135A. As described with reference to FIGS. 5A and 5B, a gap fill insulating layer 161 may be penetrated by a second tubular insulating pattern 135B. As described with reference to FIGS. 5A and 5B, a conductive gate contact 185 or 185′ may extend from a central region of the first tubular insulating pattern 135A to a central region of the second tubular insulating pattern 135B.

Referring to FIG. 6, a semiconductor memory device may include a plurality of blocking Insulating layers 105 respectively corresponding to a plurality of conductive layers 111. Each blocking insulating layer 105 may correspond to the second blocking insulating layer described with reference to FIG. 4. Each blocking insulating layer 105 may extend along a sidewall SU_S, a top surface SU_T, and a bottom surface SU_B of a conductive layer 111 corresponding thereto. The blocking insulating layer 105 may include an opening OP corresponding to a contact surface CTS. A protrusion part 185P1 of the conductive gate contact 185 may fill the opening OP, and form the contact surface CTS with a conductive layer 111 corresponding thereto.

For example, as described with reference to FIG. 5A, the plurality of conductive layers 111 may include a first conductive layer CP1 and a second conductive layer CP2, and the plurality of interlayer insulating layers 111 may include a first interlayer insulating layer ILD1 and a second Interlayer insulating layer ILD2. The second conductive layer CP2 may be a contact conductive layer in contact with a first conductive gate contact CT1.

A protrusion part 185P1 of the first conductive gate contact CT1 may form the contact surface CTS with the second conductive layer CP2 through the opening OP of the blocking insulating layer 105. The blocking insulating layer 105 may be interposed between the second conductive layer CP2 and the first Interlayer insulating layer ILD1. The blocking insulating layer 105 may extend between the first tubular insulating pattern 135A and the second conductive layer CP2.

Referring to FIG. 7, each of a plurality of conductive layers 111′ of a semiconductor memory device may continuously extend along an inner wall IN1 of a first tubular insulating pattern 135A and an inner wall IN2 of a second tubular insulating pattern 135B while passing between the first tubular Insulating pattern 135A and the second tubular insulating pattern 135B. Each conductive layer 111′ may be divided into a gate electrode pattern GE and a tubular conductive pattern 185P1′. The gate electrode pattern GE may be defined as a portion of the conductive layer 111, which surrounds the first tubular insulating pattern 135A and extend in a direction intersecting the first tubular insulating pattern 135A. The tubular conductive pattern 185P1′ may be defined as a portion of the conductive layer 111, which extends along the inner wall IN1 of the first tubular insulating pattern 135A and the inner wall IN2 of the second tubular pattern 135B from between the first tubular insulating pattern 135A and the second tubular insulating pattern 135B.

The tubular conductive pattern 185P1′ may form a conductive gate contact 185′ of the semiconductor memory device. The conductive gate contact 185′ may further include a core conductive pattern 185P2′. The core conductive pattern 185P2′ may include the same conductive material as the tubular conductive pattern 185P1′ or include a conductive material different from a conductive material of the tubular conductive pattern 185P1′. In an embodiment, the conductive layer 111′ including the tubular conductive pattern 185P1′ may include a first metal layer and a first metal barrier layer, and the core conductive pattern 185P2′ may include a second metal layer and a second metal barrier layer. The first metal layer and the second metal layer may include tungsten. The first metal barrier layer and the second metal barrier layer may include at least one of titanium nitride and titanium. The second metal barrier layer may extend along a boundary between the tubular conductive pattern 185P1′ and the core conductive pattern 185P2′.

The tubular conductive pattern 185P1′ and the core conductive pattern 185P2′ may form a protrusion part P_PR and a pillar part P_PI of the conductive gate contact 185′. In an embodiment, a portion of the tubular conductive pattern 185P1′ may form the protrusion part P_PR between the first tubular insulating pattern 135A and the second tubular insulating pattern 135B, and the other portion of the tubular conductive pattern 185P1′ may extend along the inner wall IN1 of the first tubular insulating pattern 135A and the inner wall IN2 of the second tubular insulating pattern 135B to form an outer wall of the pillar part P_PI. The core insulating pattern 185P2′ may extend from a central region of the first tubular insulating pattern 135A to a central region of the second tubular insulating pattern 135B to form a central region of the pillar part P_PI.

Hereinafter, manufacturing methods of semiconductor memory devices in accordance with embodiments of the present disclosure will be described based on a contact region of a gate stack structure.

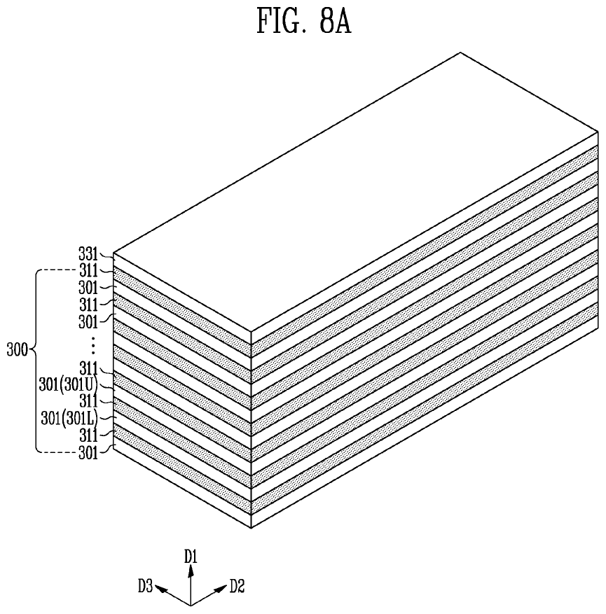

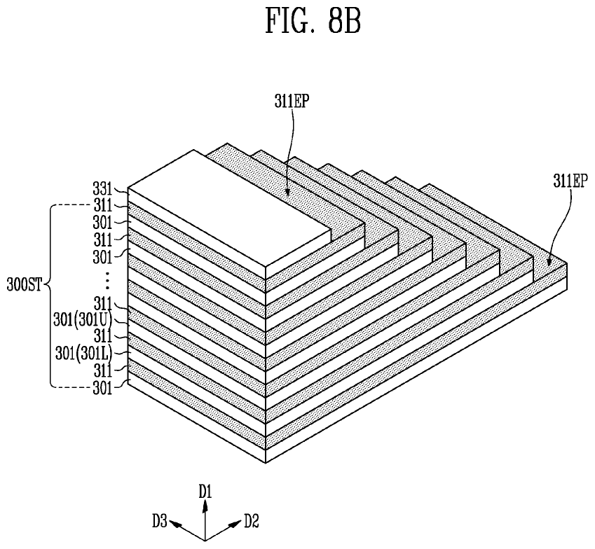

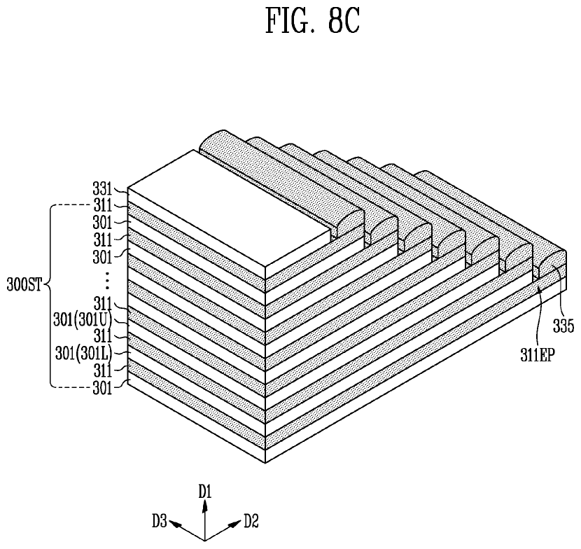

FIGS. 8A, 8B, 8C, 9A, 9B, 10A, 10B, 10C, 11, 12A, 12B, and 13 are process sectional views illustrating a manufacturing method of a semiconductor memory device in accordance with an embodiment of the present disclosure.

FIGS. 8A to 8C are perspective views illustrating a process of forming a stepped stack structure and a sacrificial pad.

Referring to FIG. 8A, a stack structure 300 may be formed on a pre-prepared lower structure (not shown). The lower structure may include a peripheral circuit structure and a doped semiconductor structure or may include a sacrificial substrate. The stack structure 300 may include a plurality of first material layers 301 and a plurality of second material layers 311, which are alternately disposed in the first direction D1.

The plurality of first material layers 301 may include a lower first material layer 301L and an upper first material layer 301U disposed to be spaced apart from the lower first material layer 301L in the first direction D1. One layer among the plurality of second material layers 311 may be disposed between the lower first material layer 301L and the upper first material layer 301U.

The plurality of second material layers 311 may be formed of a material different from a material of the plurality of first material layers 301. In an embodiment, each of the plurality of first material layers 301 may be formed of an insulating material for interlayer insulating layers, and the plurality of second material layers 311 may be formed of a material having an etch selectivity with respect to the plurality of first material layers 301. In an embodiment, the plurality of first material layers 301 may include an oxide layer such as silicon oxide, and the plurality of second material layers 311 may include a nitride layer such as silicon nitride.

Subsequently, an upper insulating layer 331 may be formed on the stack structure 300. The upper insulating layer 331 may be formed of a material different from the material of the plurality of second material layers 311. In an embodiment, the upper insulating layer 331 may include an oxide layer such as silicon oxide.

Referring to FIG. 8B, the upper insulating layer 331, the plurality of first material layers 301, and the plurality of second material layers 311 may be etched such that a stepped stack structure 300ST is formed. An end portion 311 EP of each of the plurality of second material layers 311 may protrude more laterally than a first material layer 301 or the upper insulating layer 331, which is disposed on the top thereof. In an embodiment, the end portion 311 EP of the second material layer 311 may extends farther than the first material layer 301 disposed above the end portion 311 EP or the upper insulating layer 331 disposed above the end portion 311 EP, in the second direction D2. Accordingly, the end portion 311 EP of each of the plurality of second material layers 311 may form a step of the stepped stack structure 300ST. For example, an end portion 311EP of a second material layer 311 disposed between the lower first material layer 301L and the upper first material layer 301U may protrude more laterally than the upper first material layer 301U.

Referring to FIG. 8C, a plurality of sacrificial pads 335 may be respectively formed on the plurality of second material layers 311. Each of the plurality of sacrificial pads 335 may be formed on an end portion 311EP of a second material layer 311 corresponding thereto and extend along the end portion 311EP of the second material layer 311.

Each sacrificial pad 335 may be formed of a material having an etch selectivity with the plurality of first material layers 301, the plurality of material layers 311, and the upper insulating layer 331. In an embodiment, the sacrificial pad 335 may include a carbon containing layer. In an embodiment, the carbon containing layer may include at least one of silicon oxynitride (e.g., SiOC) and silicon carbonitride (e.g., SiON).

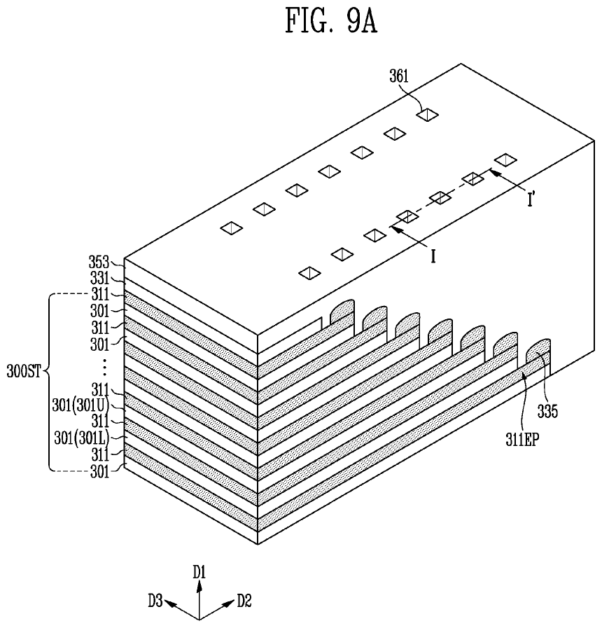

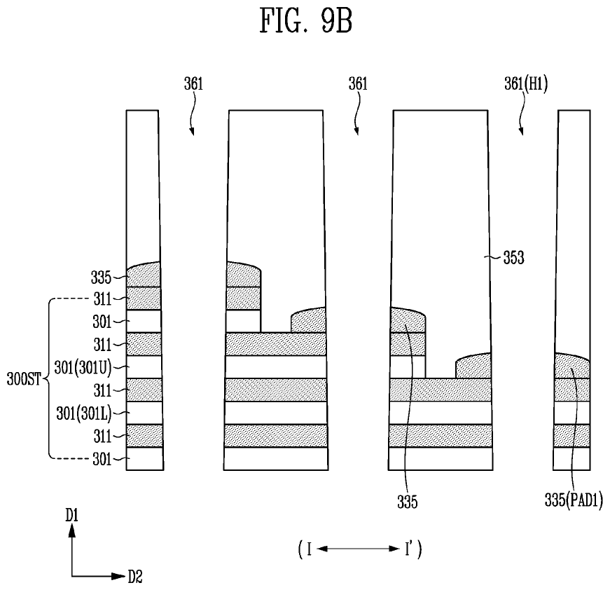

FIGS. 9A and 9B illustrate a process continued after the process shown in FIG. 8C. FIGS. 9A and 9B are perspective and sectional views illustrating a process of forming a hole. FIG. 9B is a sectional view of an intermediate process result taken along line I-I′ shown in FIG. 9A.

Referring to FIGS. 9A and 9B, a gap fill insulating layer 353 may be formed on the stepped stack structure 300ST. The gap fill insulating layer 353 may extend to cover the plurality of sacrificial pads 335 and the upper insulating layer 331. The gap fill insulating layer 353 may extend between the plurality of sacrificial pads 335 and the upper insulating layer 331 and extend between the plurality of sacrificial pads 335 and the plurality of first material layers 301.

The gap fill insulating layer 353 may be formed of a material having an etch selectivity with respect to the plurality of sacrificial pads 335. In an embodiment, the gap fill insulating layer 353 may include an oxide layer.

Subsequently, a plurality of holes 361 may be formed to penetrate the plurality of sacrificial pads 335, respectively. The plurality of holes 361 may penetrate the gap fill insulating layer 353 and the stepped stack structure 300ST. For example, the plurality of holes 361 may include a first hole H1, and the plurality of sacrificial pads 335 may include a first sacrificial pad PAD1. The first sacrificial pad PAD1 may overlap with an end portion 311EP of a second material layer 311 disposed between the lower first material layer 301L and the upper first material layer 301U. The first hole H1 may penetrate the first sacrificial pad PAD1, a second material layer 311 corresponding thereto, and the lower first insulating layer 301L, and extend in a direction opposite to the first direction D1 to completely penetrate the stepped stack structure 300ST. The first hole H1 may extend in the first direction D1 to penetrate the gap fill insulating layer 353.

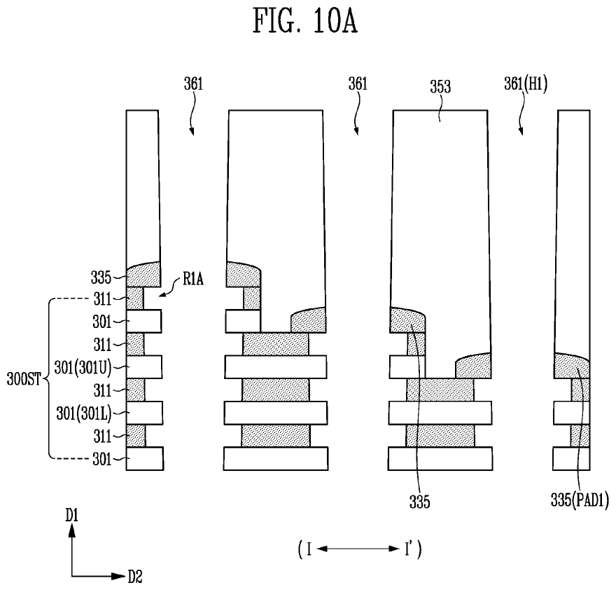

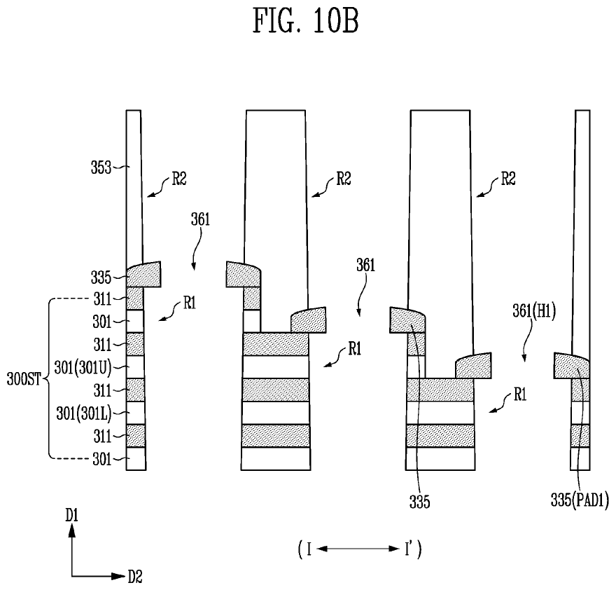

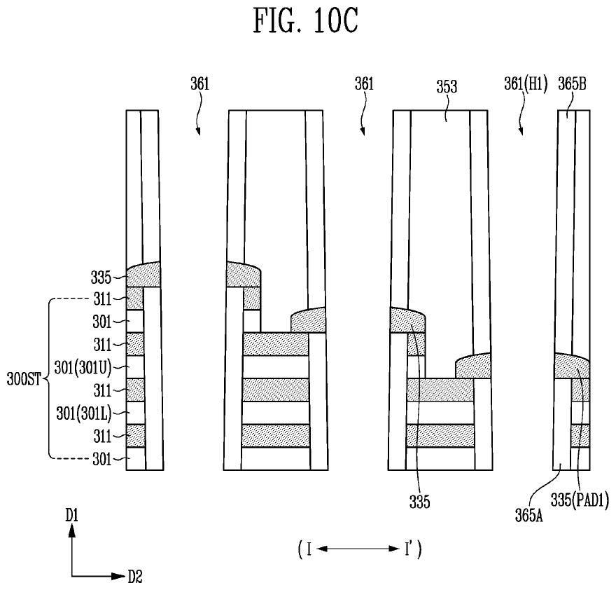

FIGS. 10A to 10C are sectional views illustrating subsequent processes continued after the process shown in FIGS. 9A and 9B. FIGS. 10A to 10C are sectional views illustrating a process of forming a first tubular insulating pattern and a second tubular insulating pattern.

Referring to FIG. 10A, a portion of each of the plurality of second material layers 311 exposed through the plurality of holes 361 may be selectively removed such that a plurality of preliminary first recess regions R1A are formed. Accordingly, the plurality of first material layers 301 may remain in a structure in which the plurality of first material layers 301 protrude more laterally toward the plurality of holes 361 than the plurality of sacrificial pads 335 and the plurality of second material layers 311.

Referring to FIG. 10B, a portion of each of the plurality of second material layers 311 may be selectively removed through the plurality of holes 361. Accordingly, a first recess region R1 may be formed under each of the plurality of sacrificial pads 335. The first recess region R1 is an area in which a plurality of first material layers 301 and a plurality of second material layers 311, which overlap with a sacrificial pad 335 corresponding thereto, are removed, and may have an area further extending than an area of the preliminary first recess region R1A.

The first recess region R1 may extend in the first direction D1 along a sidewall of at least one first material layer 301 and a sidewall of at least one second material layer 311. For example, a first recess region R1 corresponding to the first hole H1 may extend in the first direction D1 along a sidewall of a second material layer 311 disposed between the lower first material layer 301L and the upper first material layer 301U and a sidewall of the lower first material layer 301L.

While the first recess region R1 is formed, a second recess region R2 may be formed by removing a side portion of the gap fill insulating layer 353 through the plurality of holes 361. The second recess region R2 may be aligned with the first recess region R1 in the first direction D1.

Referring to FIG. 10C, a tubular insulating layer may be formed to fill the first recess region R1 and the second recess region R2, which are shown in FIG. 10B. Subsequently, a side portion of the tubular insulating layer may be etched such that the plurality of sacrificial pads 335 are exposed. Accordingly, the tubular insulating layer may be isolated into a first tubular insulating pattern 365A and a second tubular insulating pattern 365B by a sacrificial pad 335 corresponding thereto. The first tubular insulating pattern 365A may be disposed in the first recess region R1 shown in FIG. 10B. The second tubular insulating pattern 365B may be disposed in the second recess region R2 shown in FIG. 10B.

The first tubular insulating pattern 365A may extend in the first direction D1 along a sidewall of at least one first material layer 301 and a sidewall of at least one second material layer 311, which form a common plane with the first recess region R1 shown in FIG. 10B. For example, a first tubular insulating pattern 365A corresponding to the first hole H1 may extend along a sidewall of a second material layer 311 disposed between the lower first material layer 301L and the upper first material layer 301U and a sidewall of the lower first material layer 301L.

The second tubular insulating pattern 365B may extend along a sidewall of the gap fill insulating layer 353, which forms a common plane with the second recess region R2 shown in FIG. 10B.

Although not shown in the drawing, the tubular insulating layer may be formed to fill the preliminary first recess region R1A shown in FIG. 10A, before the process shown in FIG. 10B is performed. In the process of filling the preliminary first recess region R1A shown in FIG. 10A with the tubular insulating layer, voids or seams may occur inside the tubular insulating layer. The voids or seams inside the tubular insulating layer may deteriorate an insulating characteristic between conductive layers adjacent to each other in the first direction D1 and increase a leakage current. The conductive layers may be formed in a subsequent process of replacing the plurality of second material layers 311 with a plurality of conductive layers. On the other hand, in accordance with an embodiment in which the tubular insulating layer is formed in the first recess region R1 shown in FIG. 10B, occurrence of voids or seams inside the tubular insulating layer may be reduced as compared with when the tubular insulating layer is formed in the preliminary first recess region R1A.

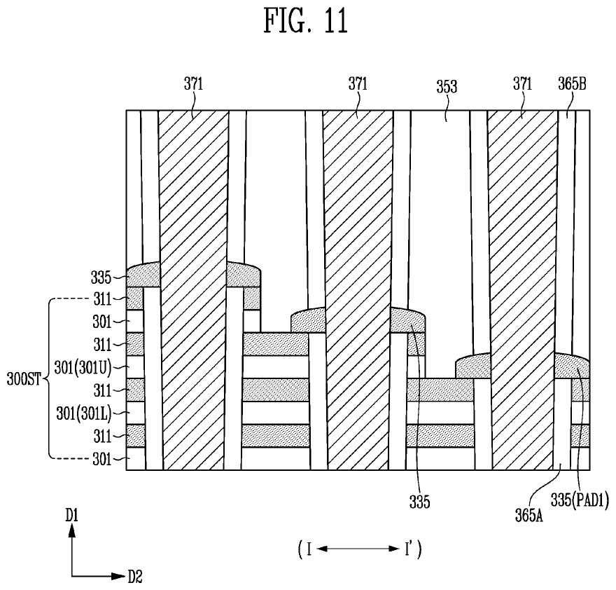

FIG. 11 illustrates a process continued after the process shown in FIG. 10C and is a sectional view illustrating a process of forming a sacrificial pillar.

Referring to FIG. 11, a sacrificial pillar 371 may be formed inside each of the plurality of holes 361 shown in FIG. 10C. The sacrificial pillar 371 may be formed of a material having an etch selectivity with respect to the sacrificial pad 335, the first tubular insulating pattern 365A, and the second tubular insulating pattern 365B. In an embodiment, the sacrificial pillar 371 may include at least one of an amorphous carbon layer, a poly-silicon layer, and a metal layer.

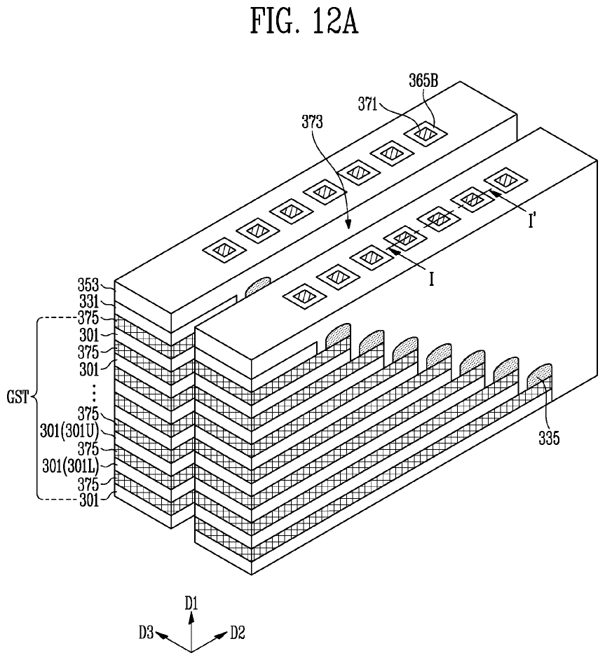

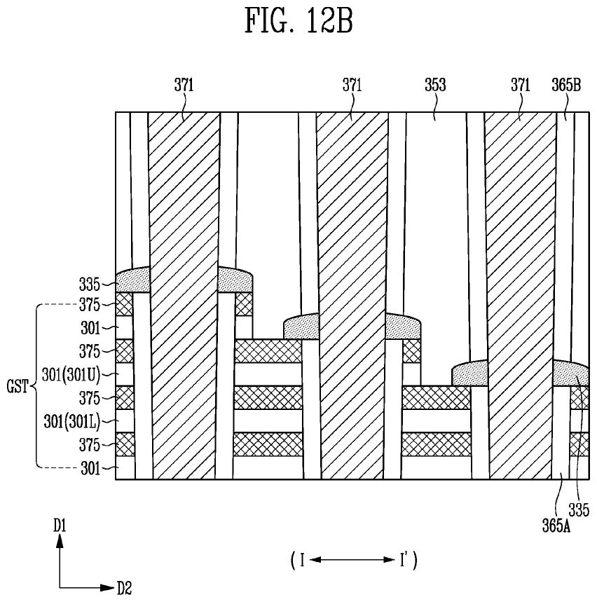

FIGS. 12A and 12B illustrate a process continued after the process shown in FIG. 11. FIGS. 12A and 12B are perspective and sectional views illustrating a process of replacing the plurality of second material layers with a plurality of conductive layers. FIG. 12B is a sectional view of an intermediate process result taken along line I-I′ shown in FIG. 12A.

Referring to FIGS. 12A and 12B, a slit 373 may be formed by etching the gap fill insulating layer 353 and the stepped stack structure 300ST shown in FIG. 11. The slit 373 may penetrate the gap fill insulating layer 353 and the stepped stack structure 300ST shown in FIG. 11.

Subsequently, the plurality of second material layers 311 shown in FIG. 11 may be replaced with a plurality of conductive layers 375 through the slit 373. Accordingly, a gate stack structure GST including a stepped structure may be formed at both sides of the slit 373.

The gate stack structure GST may include a plurality of first material layers 301 and a plurality of conductive layers 375, which are alternately stacked in the first direction D1. Each first material layer 301 may be used as an interlayer insulating layer. A sacrificial pad 335 corresponding to each of the plurality of conductive layers 375 may remain at an end portion of each of the plurality of conductive layers 375. The plurality of conductive layers 375 may be spaced apart from the sacrificial pillar 375 by the first tubular insulating pattern 365A.

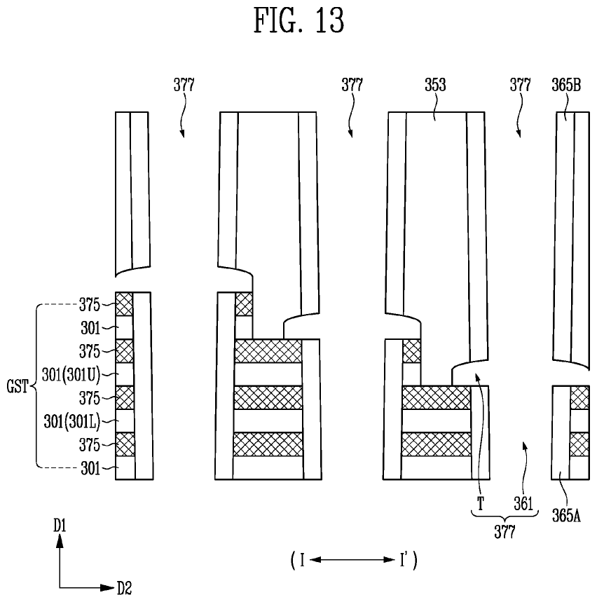

FIG. 13 illustrates a process continued after the process shown in FIGS. 12A and 12B and is a sectional view illustrating a process of removing the sacrificial pillar and the sacrificial pad.

Referring to FIG. 13, the sacrificial pillar 371 shown in FIGS. 12A and 12B may be removed. Accordingly, the plurality of holes 361 may be opened, and the first tubular insulating pattern 365A, the second tubular insulating pattern 365B, and the sacrificial pad 335 shown in FIGS. 12A and 12B may be exposed.

Subsequently, the sacrificial pad 335 shown in FIGS. 12A and 12B may be removed. A trench T may be formed in a region in which the sacrificial pad 335 is removed. The trench T may extend to the inside of the gap fill insulating layer 353 from a sidewall of a hole 361 corresponding thereto. The trench T may expose a conductive layer 375 corresponding thereto. The trench T may be opened between the first tubular insulating pattern 365A and the second tubular insulating pattern 365B and may extend in a direction intersecting the hole 361 along an end portion of the conductive layer 375. In an embodiment, the trench T may extend in the third direction D3 shown in FIG. 12A.

The trench T and the hole 361, which are connected to each other, may be defined as a contact region 377.

Subsequently, a conductive gate contact may be formed in the contact region 377. In an embodiment, the conductive gate contact 185 described with reference to FIGS. 5A and 5B may be formed in the contact region 377. The protrusion part 185P1 of the conductive gate contact 185 described with reference to FIGS. 5A and 5B may be a portion formed in the trench T shown in FIG. 13 and may correspond to the replaced part of the sacrificial pad 335 shown in FIGS. 12A and 12B. The pillar part 185P2 of the conductive gate contact 185 described with reference to FIGS. 5A and 5B may be a portion formed in the hole 361 shown in FIG. 13.

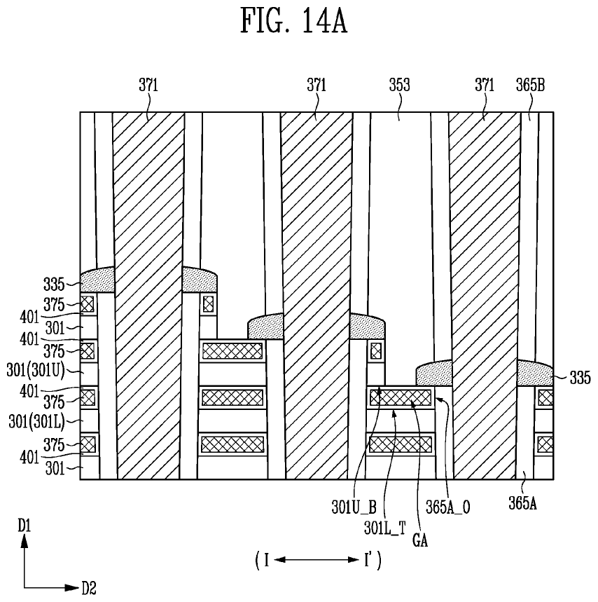

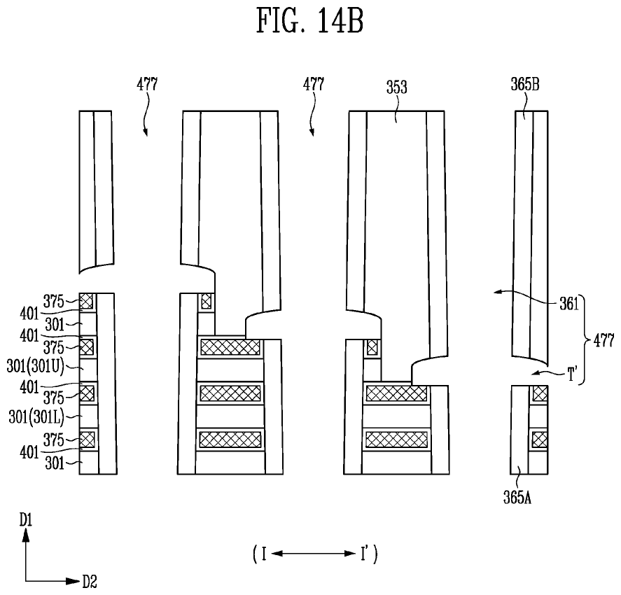

FIGS. 14A and 14B are process sectional views illustrating a manufacturing method of a semiconductor memory device in accordance with an embodiment of the present disclosure.

FIG. 14A illustrates a process continued after the process shown in FIG. 11 and is a sectional view illustrating a process of forming a plurality of conductive layers.

Referring to FIG. 14A, as described with reference to FIG. 11, a sacrificial pillar 371 may be formed inside each of the plurality of holes 361 shown in FIG. 10C. Subsequently, the slit 373 shown in FIG. 12A may be formed. Subsequently, the plurality of second material layers 311 shown in FIG. 11 may be removed through the slit 373 shown in FIG. 12A such that a plurality of gate regions GA are opened.

The plurality of first material layers 301 and the first tubular insulating layer 365A may be exposed through the plurality of gate regions GA. For example, a top surface 301L_T of the lower first material layer 301L, a bottom surface 301U_B of the upper first material layer 301U, and an outer wall 365A_O of the first gap fill insulating layer 365A may be exposed by a gate region GA between the lower first material layer 301L and the upper first material layer 301U.

Subsequently, a blocking insulating layer 401 may be formed along a surface exposed through each gate region GA. For example, the blocking insulating layer 401 may be conformally formed along the top surface 301L_T of the lower first material layer 301L, the bottom surface 301U_B of the upper first material layer 301U, and the outer wall 365A_O of the first gap fill insulating layer 365A. The blocking insulating layer 401 may be formed of an insulating material such as a silicon oxide layer, a silicon oxynitride layer, or a metal oxide layer. In an embodiment, the blocking insulating layer 401 may include an aluminum oxide layer.

Subsequently, a conductive material may be introduced through the slit 373 shown in FIG. 12A, so that a conductive layer 375 may be formed inside the gate region GA opened by the blocking insulating layer 401. Accordingly, a gate stack structure including a plurality of first material layers 301 and a plurality of conductive layers 375, which are alternately stacked in the first direction D1, may be formed.

FIG. 14B illustrates a process continued after the process shown in FIG. 14A and is a sectional view illustrating a contact region exposing the conductive layer.

Referring to FIG. 14B, the sacrificial pillar 371 shown in FIG. 14A may be removed. Accordingly, a plurality of holes 361 may be opened, and the first tubular insulating pattern 365A, the second tubular insulating pattern 365B, and the sacrificial pad 335 shown in FIG. 14A may be exposed.

Subsequently, the sacrificial pad 335 shown in FIG. 14A may be removed. Subsequently, a portion of the blocking insulating layer 401 may be removed. The portion of the blocking insulating layer 401 may be a portion exposed by removing the sacrificial pad 335 shown in FIG. 14A. The sacrificial pad 335 shown in FIG. 14A and the portion of the block insulating layer 401 are removed, so that a trench T′ is formed. The trench T′ may extend to the inside of the gap fill insulating layer 353 from a sidewall of a hole 361 corresponding thereto. The trench T′ and the hole 361, which are connected to each other, may be defined as a contact region 477.

Subsequently, a conductive gate contact may be formed in the contact region 477. In an embodiment, the conductive gate contact 185 described with reference to FIG. 6 may be formed in the contact region 477. The protrusion part 185P1 of the conductive gate contact 185 described with reference to FIG. 6 may be formed in the trench T′ shown in FIG. 14B, and the pillar part 185P2 of the conductive gate contact 185 described with reference to FIG. 6 may be formed in the hole 361 shown in FIG. 14B.

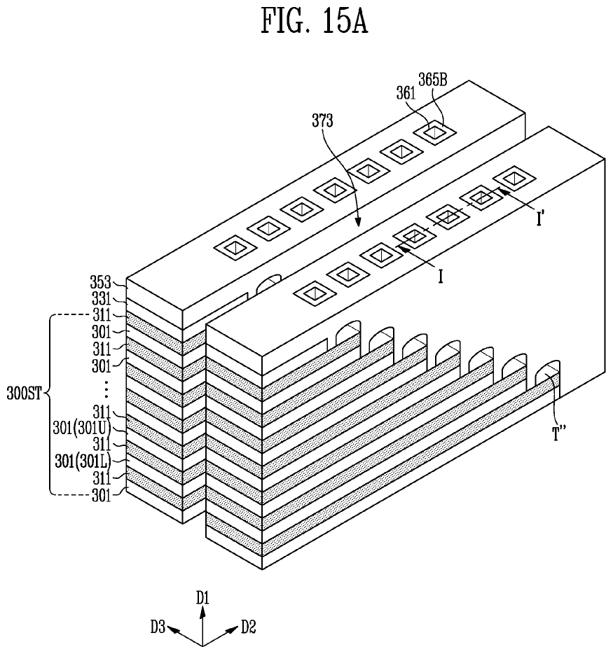

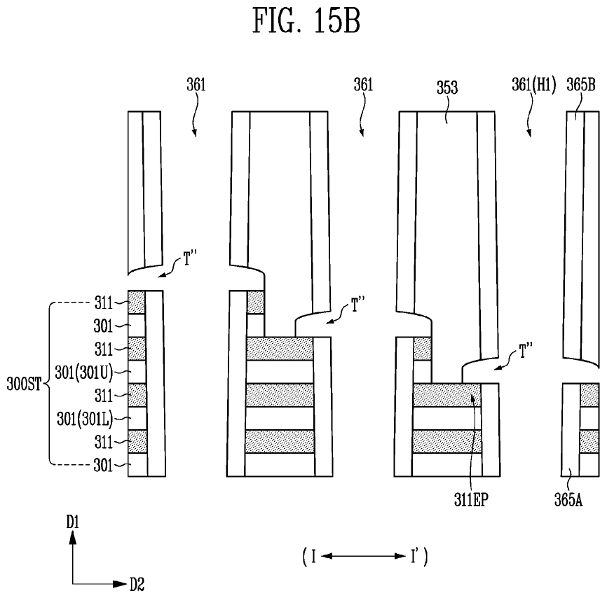

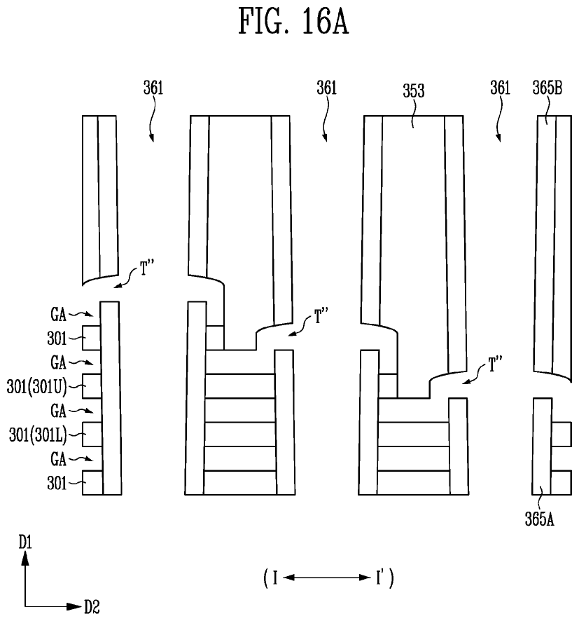

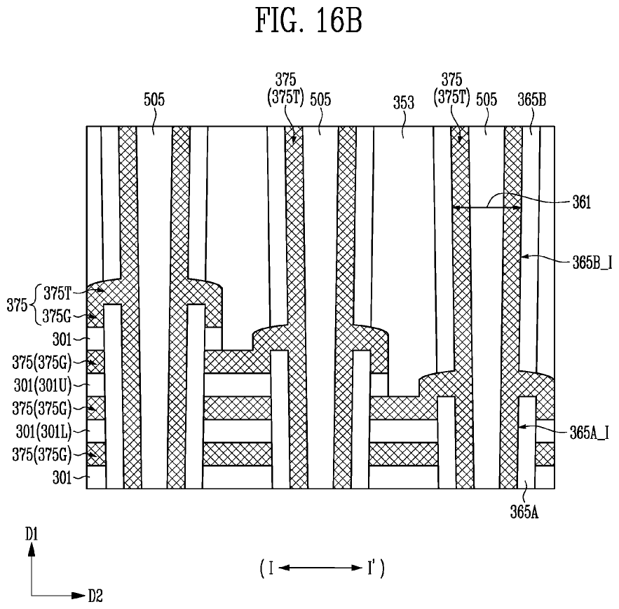

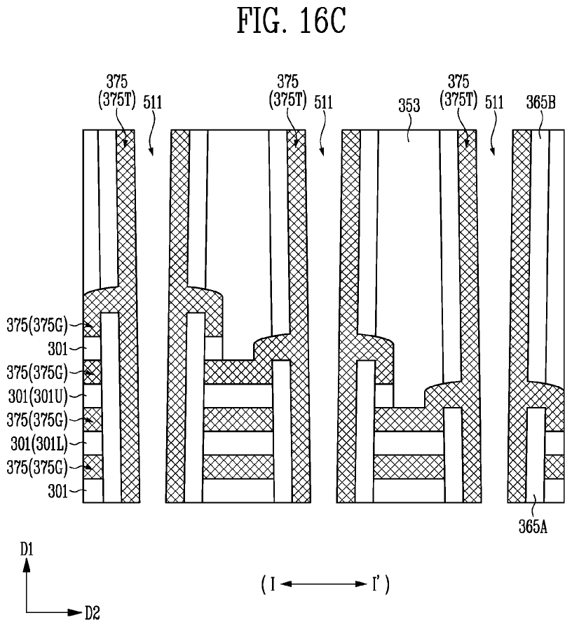

FIGS. 15A, 15B, 16A, 16B, and 16C are process views illustrating a manufacturing method of a semiconductor memory device in accordance with an embodiment of the present disclosure.

FIGS. 15A and 15B illustrate a process continued after the process shown in FIG. 10C, and perspective and sectional views illustrating a process of a slit 373 and a trench T″. FIG. 15B is a sectional view taken along line I-I′ shown in FIG. 15A.

Referring to FIGS. 15A and 15B, a slit 373 may be formed by etching the stepped stack structure 300ST shown in FIG. 10C. The slit 373 may penetrate the gap fill insulating layer 353 and the stepped stack structure 300ST shown in FIG. 10C.

Subsequently, the sacrificial pad 335 shown in FIG. 10C may be removed through the slit 373. A trench T″ may be formed in a region in which the sacrificial pad 335 is removed. The trench T″ may extend to the inside of the gap fill insulating layer 353 from a sidewall of a hole 361 corresponding thereto. The trench T″ may expose an end portion 311EP of a second material layer 311 corresponding thereto. For example, the trench T″ connected to the first hole H1 may expose an end portion 311EP of a second material layer 311 disposed between the lower first material layer 301L and the upper first material layer 301U.

The first trench T″ may be opened between the first tubular insulating pattern 365A and the second tubular insulating layer 365B and may extend toward the slit 373 along the end portion 311EP of the second material layer 311. In an embodiment, the trench T″ may extend in the third direction D3 along the end portion 311EP of the second material layer 311.

FIGS. 16A to 16C are sectional views illustrating a process continued after the process shown in FIGS. 15A and 15B.

Referring to FIG. 16A, the plurality of second material layers 311 shown in FIGS. 15A and 15B may be removed through the slit 373 shown in FIGS. 15A and 15B, the plurality of holes 361, and the trench T″ such that a plurality of gate regions GA are opened. Each gate region GA may be connected to a trench T″ corresponding thereto.

Referring to FIG. 16B, a conductive layer 375 may be formed inside the gate area GA and the trench T″, which are shown in FIG. 16A. The conductive layer 375 may continuously extend along an inner wall 365A_I of the first tubular insulating pattern 365A and an inner wall 365B_I of the second tubular insulating pattern 365B. The conductive layer 375 may be divided into a gate electrode pattern 375G and a tubular conductive pattern 375T. The gate electrode pattern 375G may be a portion of the conductive layer 375 disposed inside the gate region GA shown in FIG. 16A. The tubular conductive pattern 375T may be a portion of the conductive layer 375 extending along the inner wall 365A_I of the first tubular insulating pattern 365A and the inner wall 365B_I of the second tubular insulating pattern 365B from the inside of the trench T″ shown in FIG. 16A.

Although not shown in the drawing, before the conductive layer 375 is formed, a blocking insulating layer (not shown) may be formed along a surface of each of the gate region GA, the trench T″, and the hole 361, which are shown in FIG. 16A. A surface of the gate electrode pattern 375G may be surrounded by the blocking insulating layer (not shown), and the blocking insulating layer may extend between the first tubular insulating pattern 365A and the conductive layer 375 and between the second tubular insulating pattern 365B and the conductive layer 375.

Subsequently, a protective layer 505 may be formed in a central region of the hole 361. The central region of the hole 361 may be a region opened by the tubular conductive pattern 375T of the conductive layer 375. The protective layer 505 may be formed of a material having an etch selectivity with respect to the gap fill insulating layer 353 and the conductive layer 375.

Referring to FIG. 16C, the protective layer 505 shown in FIG. 16B may be removed after the vertical structure 180 described with reference to FIG. 5B is formed inside the slit 373 shown in FIG. 15A. The tubular conductive pattern 375T of the conductive layer 375 may be exposed.

Subsequently, a core conductive pattern of a conductive gate contact may be formed. In an embodiment, as shown in FIG. 7, a conductive gate contact 185′ may include a core conductive pattern 185P2′. The core conductive pattern 185P2′ may be disposed in a central region 511 of the tubular conductive pattern 375T shown in FIG. 16C.

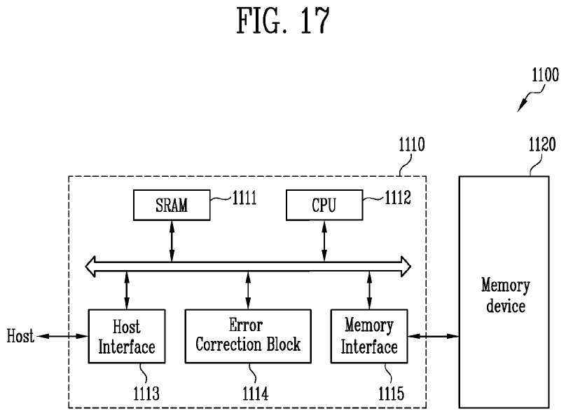

FIG. 17 is a block diagram illustrating a configuration of a memory system in accordance with an embodiment of the present disclosure.

Referring to FIG. 17, the memory system 1100 includes a memory device 1120 and a memory controller 1110.

The memory device 1120 may be a multi-chip package configured with a plurality of flash memory chips. The memory device 1120 may include a gate stack structure having a stepped structure, which includes a plurality of interlayer insulating layers and a plurality of conductive layers, a tubular insulating layer penetrating the stepped structure of the gate stack structure, and a conductive gate contact connected an end portion of one of the plurality of conductive layers, the conductive gate contact extending to a central region of the tubular insulating layer.

The memory controller 1110 controls the memory device 1120 and may include Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120 and corrects the detected error. The memory interface 1115 interfaces with the memory device 1120. The memory controller 1110 may further include Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

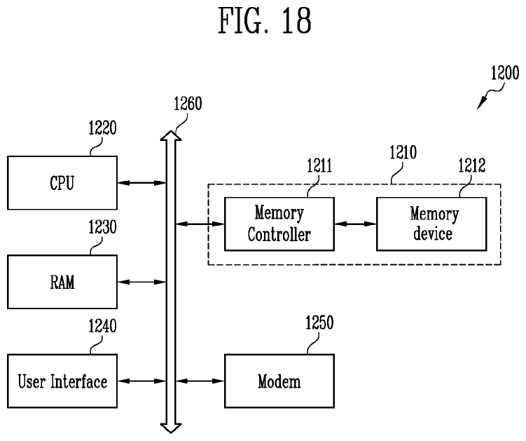

FIG. 18 is a block diagram illustrating a configuration of a computing system in accordance with an embodiment of the present disclosure.

Referring to FIG. 18, the computing system 1200 may include a CPU 1220, random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, mobile DRAM, and the like may be further included.

The memory system 1210 may be configured with a memory device 1212 and a memory controller 1211. The memory device 1212 may have the same configuration as the memory device 1120 described above with reference to FIG. 17. The memory controller 1211 may have the same configuration as the memory controller 1110 described above with reference to FIG. 17.

In accordance with various embodiments of the present disclosure, occurrence of voids or seams in a tubular insulating layer or a tubular insulating pattern may be reduced. Accordingly, the operational reliability of a semiconductor memory device may be improved.

What is claimed is:

1. A semiconductor memory device comprising:
a gate stack structure including a plurality of interlayer insulating layers and a plurality of conductive layers, which are alternately stacked in a first direction, the gate stack structure having a stepped structure defined by an end portion of each of the plurality of conductive layers extending to a different length;
a gap fill insulating layer disposed on the gate stack structure to cover the stepped structure;
a tubular insulating layer intersecting the end portion of each of the plurality of conductive layers, the tubular insulating layer extending in the first direction to penetrate the stepped structure of the gate stack structure and the gap fill insulating layer; and
a conductive gate contact disposed in a central region of the tubular insulating layer,
wherein the conductive gate contact includes a protrusion part penetrating a side portion of the tubular insulating layer to be connected to one conductive layer among the plurality of conductive layers.

2. The semiconductor memory device of claim 1, wherein the tubular insulating layer is isolated into a first tubular insulating pattern penetrating the gate stack structure and a second tubular insulating pattern penetrating the gap fill insulating layer by the protrusion part.

3. The semiconductor memory device of claim 1, wherein the tubular insulating layer continuously extends to penetrate at least one conductive layer among the plurality of conductive layers and at least one interlayer insulating layer among the plurality of interlayer insulating layers.

4. The semiconductor memory device of claim 1, further comprising a blocking insulating layer extending along a surface of each of the plurality of conductive layers,
wherein the protrusion part penetrates the blocking insulating layer.

5. The semiconductor memory device of claim 1, wherein the conductive gate contact includes a pillar part surrounded by the tubular insulating layer, the pillar part being integrated with the protrusion part.

6. The semiconductor memory device of claim 1, wherein the protrusion part of the conductive gate contact is integrated with the one conductive layer among the plurality of conductive layers.

7. A semiconductor memory device comprising:
a first conductive layer;
a second conductive layer disposed to be spaced apart from the first conductive layer in a first direction;
an interlayer insulating layer between the first conductive layer and the second conductive layer;
a first tubular insulating pattern penetrating the first conductive layer, the interlayer insulating layer, and the second conductive layer, the first tubular insulating pattern extending in the first direction;
a second tubular insulating pattern spaced apart from the first tubular insulating pattern in the first direction, the second tubular insulating pattern extending in the first direction; and
a conductive gate contact including a pillar part extending from a central region of the first tubular insulating pattern to a central region of the second tubular insulating pattern and a protrusion part extending between the first tubular insulating pattern and the second tubular insulating pattern from the pillar part, wherein the protrusion part is in contact with a top surface of the second conductive layer.

8. The semiconductor memory device of claim 7, wherein a first interface between the first tubular insulating pattern and the protrusion part and a second interface between the second tubular insulating pattern and the protrusion part overlap with each other in the first direction.

9. The semiconductor memory device of claim 7, wherein the first conductive layer extends farther than the second conductive layer in a second direction perpendicular to the first direction.

10. The semiconductor memory device of claim 7, further comprising a gap fill insulating layer formed on the protrusion part of the conductive gate contact, the gap fill insulating layer being penetrated by the second tubular insulating pattern.

11. The semiconductor memory device of claim 7, further comprising a blocking insulating layer interposed between the second conductive layer and the interlayer insulating layer, the blocking insulating layer extending between the second conductive layer and the first tubular insulating pattern,
wherein the blocking insulating layer includes an opening facing the protrusion part.

12. A semiconductor memory device comprising:
a first conductive layer;
a second conductive layer disposed to be spaced apart from the first conductive layer in a first direction;
an interlayer insulating layer between the first conductive layer and the second conductive layer;
a first tubular insulating pattern penetrating the first conductive layer, the interlayer insulating layer, and the second conductive layer, the first tubular insulating pattern extending in the first direction; and
a second tubular insulating pattern spaced apart from the first tubular insulating pattern in the first direction, the second tubular insulating pattern extending in the first direction,
wherein the second conductive layer extends along an inner wall of the first tubular insulating pattern and an inner wall of the second tubular insulating pattern while passing between the first tubular insulating pattern and the second tubular insulating pattern.

13. The semiconductor memory device of claim 12, further comprising a core conductive pattern extending toward a central region of the second tubular insulating pattern from a central region of the first tubular insulating pattern.

14. The semiconductor memory device of claim 12, wherein the first conductive layer extends farther than the second conductive layer in a second direction perpendicular to the first direction.

15. A method of manufacturing a semiconductor memory device, the method comprising:
forming a stepped stack structure including a lower first material layer, an upper first material layer disposed to be spaced apart from the lower first material layer in a first direction, and a second material layer between the lower first material layer and the upper first material layer, wherein an end portion of the second material layer extends farther than the upper first material layer in a second direction perpendicular to the first direction;
forming a sacrificial pad on the end portion of the second material layer;
forming a hole penetrating the lower first material layer, the second material layer, and the sacrificial pad;
removing a portion of each of the lower first material layer and the second material layer through the hole such that a first recess region is formed under the sacrificial pad;
forming a first tubular insulating pattern in the first recess region;
removing the sacrificial pad such that a trench is formed; and
forming a conductive gate contact in the trench and a central region of the first tubular insulating pattern.

16. The method of claim 15, wherein the first recess region and the first tubular insulating pattern extend in the first direction to form a common plane with the lower first material layer and the second material layer.

17. The method of claim 15, further comprising, before the sacrificial pad is removed:
forming a sacrificial pillar inside the hole;
forming a slit penetrating the stepped stack structure;
replacing the second material layer with a conductive layer through the slit; and
removing the sacrificial pillar such that the first tubular insulating pattern and the sacrificial pad are exposed.

18. The method of claim 17, wherein replacing the second material layer with the conductive layer through the slit includes:
removing the second material layer through the slit such that a gate region is opened;
forming a blocking insulating layer along a top surface of the lower first material layer, a bottom surface of the upper first material layer, and an outer wall of the first tubular insulating pattern, which are exposed through the gate region; and
forming the conductive layer inside the gate region opened by the blocking insulating layer.

19. The method of claim 18, wherein the sacrificial pad is removed after the conductive layer is formed, and
wherein the method further comprises removing a portion of the blocking insulating layer such that the conductive layer is exposed, after the sacrificial pad is removed.

20. The method of claim 15, further comprising:
forming a gap fill insulating layer covering the stepped stack structure and the sacrificial pad; and
forming a slit penetrating the gap fill insulating layer and the stepped stack structure,
wherein the hole extends in the first direction to penetrate the gap fill insulating layer,
wherein a second recess region in which a side portion of the gap fill insulating layer is etched through the hole is formed, while the first recess region is formed, and
wherein a second tubular insulating pattern is formed in the second recess region, while the first tubular insulating pattern is formed.

21. The method of claim 20, further comprising removing the second material layer through the slit and the trench such that a gate region is opened,
wherein forming the conductive gate contact includes forming a conductive layer filling the gate region and the trench, the conductive layer extending along an inner wall of the first tubular insulating pattern and an inner wall of the second tubular insulating pattern.

22. The method of claim 21, wherein the conductive layer includes a gate electrode pattern inside the gate region and a tubular conductive pattern extending to the inside of the trench and the hole from the gate electrode pattern.

23. The method of claim 22, wherein forming the conductive gate contact further includes forming a core conductive pattern in a central region of the tubular conductive pattern.
